(19) United States
(12) Patent Application Publication
(10) Pub. No.: US 2025/0125228 A1
(43) Pub. Date: Apr. 17, 2025

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Guendalina CATALANO, Milano (IT); Alessandro MELLINA GOTTARDO, Milano (IT); Alberto ARRIGONI, Eupilio (IT)

(73) Assignee: STMicroelectronics International N.V., Geneva (CH)

(21) Appl. No.: 18/910,661

(22) Filed: Oct. 9, 2024

(30) Foreign Application Priority Data
Oct. 17, 2023 (IT) 102023000021597

(51) Int. Cl. H01L 23/495; H01L 21/48; H01L 21/56; H01L 23/00; H01L 23/31

(52) U.S. Cl. CPC H01L 23/49513; H01L 21/4828; H01L 21/4835; H01L 21/565; H01L 23/3121; H01L 23/49555; H01L 24/32; H01L 24/48; H01L 24/73; H01L 2224/32225; H01L 2224/48091; H01L 2224/48225; H01L 2224/48463; H01L 2224/73265; H01L 2924/1815

(57) ABSTRACT

A semiconductor die is arranged at a die mounting region at a first surface of a die pad in a substrate. The die pad has a second surface opposite the first surface. Laser beam energy is applied to the second surface of the die pad to form in the second surface of the die pad a recessed peripheral portion surrounding a central portion opposite the die mounting region at the first surface. An encapsulation of electrically insulating material is molded onto the substrate. During molding, the electrically insulating material covers the recessed peripheral portion and leakage of the electrically insulating material over the central portion is countered in response to the peripheral portion of the second surface of the die pad being recessed.

### PRIORITY CLAIM

This application claims the priority benefit of Italian application for Patent No. 102023000021597 filed on Oct. 17, 2023, the content of which is hereby incorporated by reference in its entirety to the maximum extent allowable by law.

### TECHNICAL FIELD

The description relates to semiconductor devices.

One or more embodiments can be applied to semiconductor devices including integrated circuits (ICs), for instance.

### BACKGROUND

Current manufacturing processes of integrated circuit (IC) semiconductor devices comprise molding an insulating molding compound onto the devices to provide an insulating encapsulation thereto.

Resin leaks or flashes at the bottom surface of the die pad can undesirably result from the molding step and may cause inadequate plating of the bottom surface of the die pad.

For instance, resin flashes have been observed to cause formation of so-called “tin islands” at the periphery of the bottom surface of the die pad; these lumps of solder material may detach from the die pad and possibly cause undesired short circuits between the leads.

Resin flashes may be removed via de-flashing processes such as dry de-flashing via laser ablation, for instance, or chemical de-flashing.

However, conventional de-flashing processes come with the drawback of undesirably promoting delamination between the metallic material (copper, for instance) of the leadframe and the electrically insulating encapsulation.

Reference is made to United States Patent Application Publication Nos. 2020/0273813, 2011/0266662, 2022/0093494, and 2023/0187296, Japanese Patent Application No. 2017079229, and U.S. Pat. Nos. 10,366,943, 10,784,186, and 7,262,491 (all incorporated herein by reference) which provide background information in the related technological area.

There is a need in the art to overcome the drawbacks discussed in the foregoing.

### SUMMARY

One or more embodiments relate to a method.

One or more embodiments relate to a corresponding (integrated circuit) semiconductor device.

In solutions as described herein laser beam energy is applied to the bottom surface of a die pad to form therein a recessed portion that is subsequently filled with electrically insulating molding compound.

In solutions as described herein, a roughened surface is formed at the recessed portion of the die pad that enhances adhesion between the molding compound and the die pad.

In solutions as described herein, an adhesion promoter layer, possibly provided at the bottom surface of the die pad, is removed at the recessed portion thereof via laser ablation prior to molding an electrically insulating encapsulation.

Solutions as described herein may advantageously be applied to (integrated circuit) semiconductor devices provided with an exposed pad quad flat package (QFP), for instance.

### BRIEF DESCRIPTION OF THE DRAWINGS

One or more embodiments will now be described, by way of example only, with reference to the annexed figures, wherein:

FIG. 1 is a cross-sectional view of a semiconductor device;

FIG. 2 is exemplary of a possible aspect of a portion of a back or bottom surface of a device as illustrated in FIG. 1;

FIG. 3 is an enlarged view corresponding to the portion of FIG. 2 indicated by the arrow III;

FIG. 4 is an enlarged view of the portion of FIG. 1 indicated by the arrow IV;

FIGS. 5A and 5B are cross-sectional views of the same portion of a semiconductor device illustrative of processing steps; and

FIG. 6 is a cross-sectional view of a portion of a semiconductor device.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

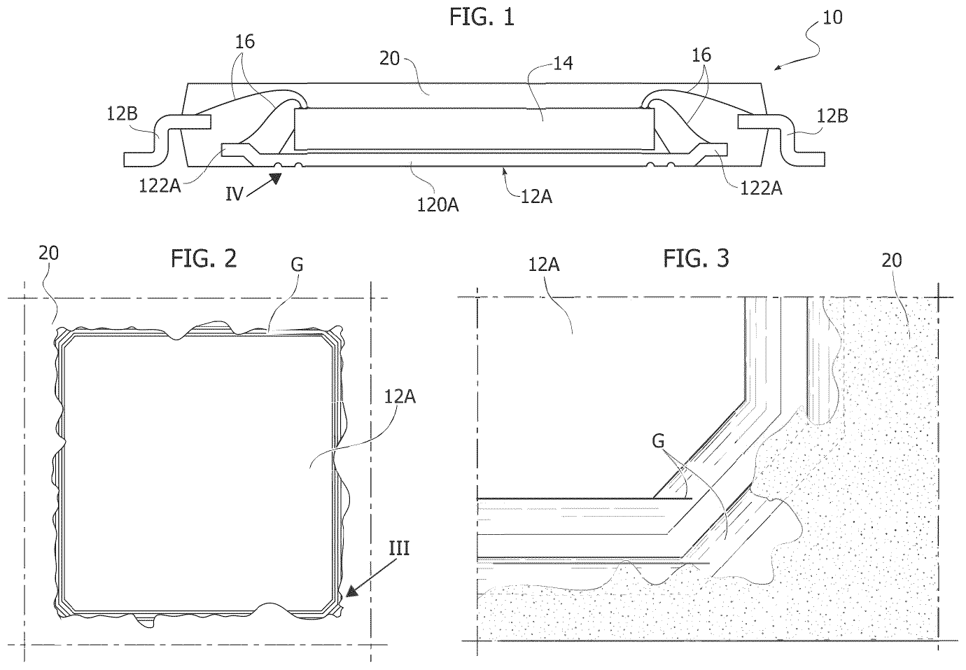

FIG. 1 is a cross-sectional view illustrative of an (integrated circuit, IC) semiconductor device 10 provided with a quad flat package (QFP).

The exemplary device 10 illustrated in FIG. 1 comprises: a semiconductor die/chip 14 (the terms chip/s and die/dice are herein regarded as synonymous) attached at the top/front surface of a die pad 12A in a leadframe, and an array of leads 12B arranged around the die pad 12A having the die 14 mounted thereon.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

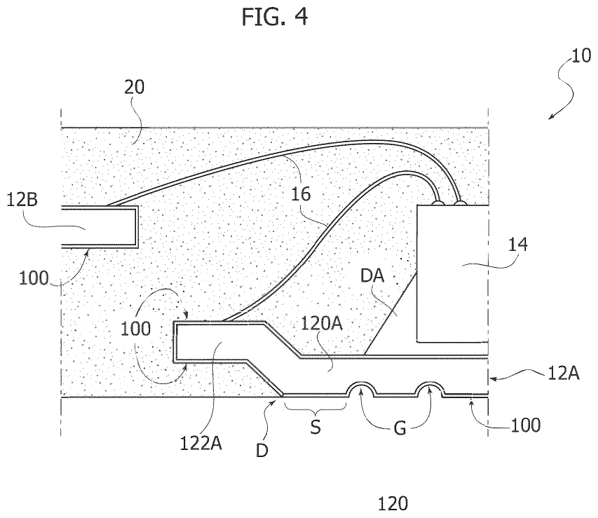

Essentially, a leadframe comprises an array of electrically-conductive formations (or leads 12B) that from an outline location extend inwardly in the direction of a semiconductor chip or die 14 thus forming an array of electrically-conductive formations from a die pad 12A configured to have at least one integrated circuit (IC) semiconductor die attached thereon. This may be via conventional means such as a die attach adhesive (a die attach (DA) film, for instance, as illustrated in FIG. 4).

As exemplified in FIG. 1, a semiconductor device 10 may be provided with a die pad 12A having a (central) die mounting region 120A and a raised rim 122A around the die mounting region giving the die pad 12A a vat-like shape.

As illustrated herein by way of example, an (integrated circuit) semiconductor device such as the device 10 may also comprise electrically conductive formations 16 (wires, for instance) that couple the semiconductor die 14 to the leads (outer pads) 12B (providing input/output signals, for instance) and/or to the die pad 12A (providing a ground level, for instance).

An electrically insulating molding compound 20 (an epoxy resin, for instance) is molded onto the assembly in order to provide the semiconductor device 10 with a protective, electrically insulating encapsulation.

Manufacturing processes for obtaining a semiconductor device 10 as illustrated in FIG. 1 are conventional in the art which makes it unnecessary to provide a more detailed discussion herein.

A semiconductor device 10 as illustrated in FIG. 1 is configured to be mounted on a support such as a printed circuit board (PCB), for instance. To that effect, solder material (tin, for instance) may be provided at the bottom surface of the die pad 12A.

FIGS. 2 and 3 (wherein FIG. 3 is an enlarged view of the portion of FIG. 2 indicated by the arrow III) illustrate the bottom surface of a die pad 12A of a (IC) semiconductor device such as the device 10 illustrated in FIG. 1.

As illustrated, a molding step as mentioned in the foregoing may undesirably result in some leaks of molding compound 20 (oftentimes referred to as molding/resin flashes) covering the bottom surface of the of the die pad 12A at the peripheral region thereof.

In order to counter the undesired resin flashes from covering a more extended portion of the bottom surface of the die pad 12A, grooves G are provided at the bottom surface of the die pad 12A. In the examples illustrated in FIGS. 2 and 3 two grooves G are provided as trenches running along the periphery of the die mounting location 120A, close to its edge, to contain resin flashes.

Resin flashes may cause inadequate plating of solder material on the bottom surface of the die pad 12A and, consequently, may give rise to issues related to mounting/soldering on the final substrate (a PCB, for instance).

Moreover, it is observed that resin flashes as illustrated, for instance, in FIG. 3, may cause so-called “tin islands” (where the reference to tin is merely due to a commonly used solder material) to form. These tin islands are small amounts of soldering material that is plated in regions of the bottom surface of the die pad 12A (at the periphery thereof, for instance) left uncovered by the molding compound 20 leaks; these “lumps” of soldering material are prone to detach from the die pad 12A (during processing, for instance) possibly causing undesired short circuits between the leads 12B, for instance, thus causing failure of the device.

According to a conventional approach, issues related to such molding flashes may be countered via so-called de-flashing processes that involve removing resin flashes formed at the bottom surface of the die pad 12A. However, de-flashing processes such as chemical or dry de-flashing processes may undesirably reduce adhesion of the molding compound 20 to the metallic (copper, for instance) leadframe possibly causing delamination of the molding compound 20.

Delamination of the molding compound 20 from the die pad 12A or lead 12B may cause humidity or contaminants to enter the package possibly reaching the semiconductor die 14 and causing failure of the device 10.

Moreover, delamination caused by chemical de-flashing may be more severe when adhesion promoters (such as non-etching adhesion promoters (NEAP)) are used to enhance adhesion between the molding compound 20 and the leadframe 12A, 12B.

FIG. 4 is an enlarged view of the portion of FIG. 1 indicated by the arrow IV that illustrates an adhesion promoter (NEAP, for instance) layer 100 provided at the interface between the molding compound 20 and the leadframe 12A, 12B.

The adhesion promoter layer 100 may be at least partly dissolved when devices 10 are processed in a de-flashing bath, possibly causing delamination issues. It is observed that delamination is more likely to start at a line D, that is the points at the interface between the die pad 12A and the molding compound 20 that are exposed to a de-flashing bath.

According to another conventional approach, a dry de-flashing process can be used to remove molding compound flashes at the bottom surface of the die pad 12A.

Dry de-flashing may involve applying laser beam energy to the bottom surface of the die pad 12A to remove the undesired resin flashes via laser ablation.

However, in order to counter undesired ablation of molding compound of the package, laser ablation does not conventionally extend to the edge of the back/bottom surface of the die pad 12A exposed at the bottom of the device 10.

In other words, laser beam energy is not applied to a “safety” zone S (of about 100 microns, for instance) at the periphery of the back/bottom surface of the die pad 12A exposed at the bottom surface of the device 10 (on the right of the interface line D in FIG. 4) in order not to undesirably ablate molding compound 20 forming the electrically insulating encapsulation (on the left of the interface line D in FIG. 4).

Solutions as described herein involve applying laser beam energy to the bottom surface of a die pad to form therein a recessed portion that is subsequently filled with electrically insulating material during molding.

In solutions as described herein, a roughened surface may be formed at the recessed portion of the die pad that enhances adhesion between the molding compound and the die pad.

In solutions as described herein, an adhesion promoter layer possibly provided at the bottom surface of the die pad is removed at the recessed portion thereof via laser ablation, prior to molding an electrically insulating encapsulation.

Solutions as described herein may advantageously be applied to (integrated circuit) semiconductor devices provided with an exposed pad quad flat package (QFP) as the semiconductor device 10 illustrated in FIG. 1, for instance.

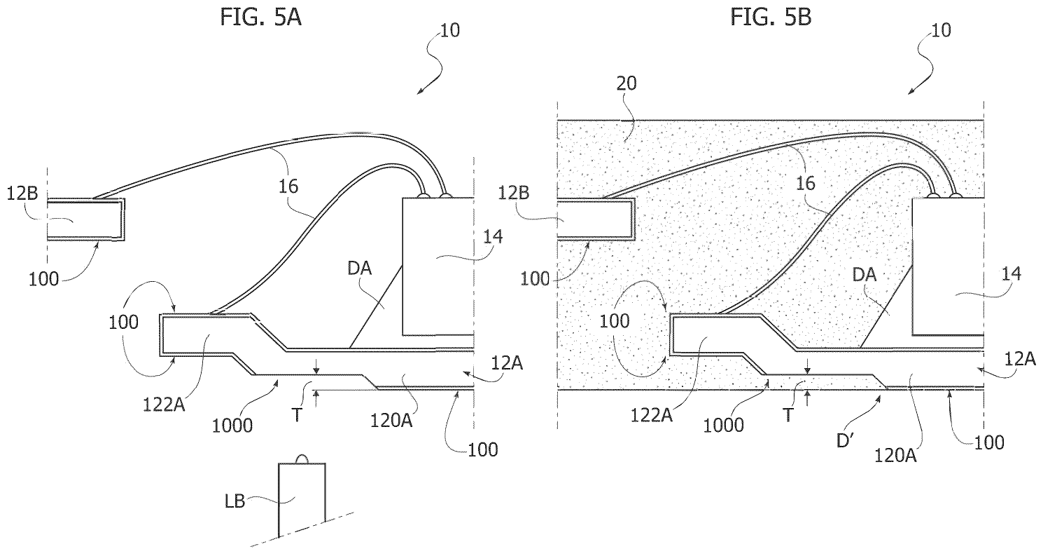

FIGS. 5A and 5B are illustrative of processing steps according to embodiments of the present description applied to a semiconductor device such as the semiconductor device 10 exemplified in FIG. 1.

As known to those skilled in the art, a plurality of semiconductor devices (such as the semiconductor device 10 illustrated in FIG. 1) can be concurrently processed by providing a common substrate (such as a leadframe reel or panel, for instance) comprising a plurality of individual substrates/leadframes. Individual leadframes may be held together via connecting bars (or dam bar) running around the periphery of each (individual) leadframe. A final singulation step removes the connecting bars (dam bars) to obtain a plurality of individual semiconductor devices.

For simplicity and ease of explanation, the following description will refer to manufacturing a single device.

It will be appreciated that the details of the structure of a device 10 as discussed herein are merely exemplary of a device where solutions as described herein may advantageously be applied, and shall not be construed in a limiting sense.

For instance, those skilled in the art may appreciate that solutions as described herein may be applied, for instance, also in case of other packages having an exposed die pad such as quad flat no leads packages (QFN) and/or to leadframes having no downset between the die pad 12A and the leads 12B and/or to die pads 12A not having a raised rim 122A.

FIG. 5A is illustrative of a semiconductor die 14 mounted (via die attach material DA, for instance) at the top/front surface of a die pad 12A, at a die mounting region 120A thereof.

As illustrated, laser beam energy LB is applied to the back/bottom surface of the die pad 12A, at the periphery of the bottom surface of the die pad 12A to form therein a recessed portion 1000. That is, metallic material (copper, for instance) of the die pad 12A (i.e., a portion of the copper die pad) is removed from the back/bottom surface thereof via laser ablation to form a recessed portion 1000 along the periphery of the back/bottom surface of the die pad 12A.

As illustrated, the recessed peripheral portion 1000 surrounds a central portion of the back/bottom surface that is opposite of the die mounting region 120A at the front/top surface of the die pad 12A.

The recessed peripheral portion 1000 of the back/bottom surface of the die pad 12A may be formed with a depth, indicated with the reference T in FIG. 5A, in the range of 25 to 35 microns, for instance.

In exemplary case illustrated in FIG. 5A, an adhesion promoter layer (a NEAP layer, for instance) is provided on the surface of the leadframe (that is, the die pad 12A and the leads 12B).

As illustrated, applying laser beam energy LB to form the peripheral recessed region 1000 of the back/bottom surface of the die pad 12A results in the adhesion promoter layer 100 being removed (ablated) at the peripheral recessed region 1000.

FIG. 5B is illustrative of a molding step where an electrically insulating encapsulation material 20 (such as an epoxy resin, for instance) is molded onto the substrate (a leadframe, for instance) 12A, 12B having a semiconductor die 14 mounted thereon, subsequently to forming the recessed portion 1000 as described in the foregoing.

As illustrated, the (electrically insulating) molding compound 20 fills the recessed peripheral portion 1000 of the back/bottom surface of the die pad 12A thus forming a layer (having a thickness notionally equal to the depth T of the recessed portion 1000) of encapsulation material 20 that covers the back/bottom surface of the die pad 12A at the recessed portion 1000.

Said otherwise, subsequently to the molding step, the bottom surface of a device 10 comprises: a central, inner region of the bottom surface of the die pad 12A (inwardly of the border line D′) where the metallic material of the die pad 12A is not covered by the encapsulation material 20; and a peripheral, outer region of the bottom surface of the die pad 12A, that is, the peripheral recessed portion 1000, where the metallic material of the die pad 12A is covered by encapsulation material 20.

As illustrated, in devices where the die pad 12A comprises a raised rim 122A around the die mounting region 120A, the peripheral rim 122A is embedded in the encapsulation material 20.

It is observed that a peripheral recessed region 1000 formed at the die mounting region 120A counters undesired leakage of molding material over the central portion of the back/bottom surface of the die pad 12A.

Moreover, applying laser beam energy LB to form a peripheral recessed portion 1000 as illustrated in the figures, has the effect of roughening the back/bottom surface of the die mounting region 120A at the peripheral recessed portion 1000.

As used herein, according to common usage, a surface being “roughened” indicates that such a surface is made rough.

A rough surface has been found to promote adhesion between the encapsulation material 20 and the die pad 12A, thus reducing the risk of delamination.

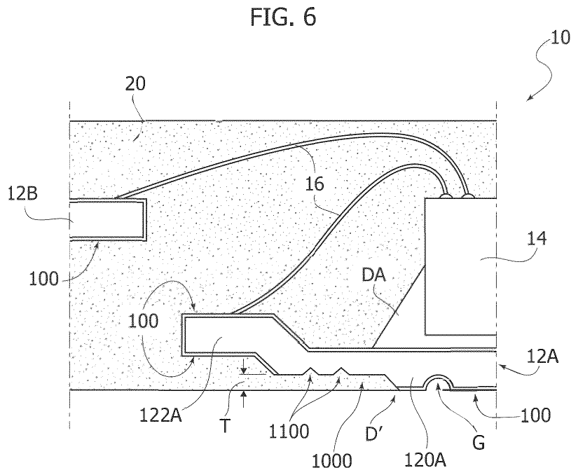

In summary, solutions as described herein in relation to FIGS. 5A, 5B and 6, involve molding an encapsulation 20 of electrically insulating material (an epoxy resin, for instance) onto a substrate (such as a leadframe comprising die pad 12A and leads 12B) having at (least one) semiconductor die 14 arranged thereon.

As illustrated in the figures, the semiconductor die 14 is arranged at a die mounting region 120A at a first (top/front) surface of a die pad 12A in the substrate, with wherein the die pad 12A having a second (bottom/back) surface opposite the first surface.

Laser beam energy LB is applied to the second surface of the die pad 12A to form therein a recessed peripheral portion 1000 (preferably, having a depth between 25 and 35 microns) surrounding a central portion opposite the die mounting region 120A at the first surface.

During molding, the electrically insulating material 20 covers the recessed peripheral portion 1000 and leakage of the electrically insulating material 20 over said central portion is countered in response to the peripheral portion 1000 of the second surface of the die pad 12A being recessed.

Advantageously, the recessed peripheral portion 1000 of the second surface of the die pad 12A is roughened in response to laser beam energy LB applied thereto, thus facilitation adhesion of the electrically insulating material 20 to the recessed peripheral portion.

FIG. 6 illustrates embodiments of the present description wherein adhesion between metallic material of the die pad 12A and the molding compound 20 may be further facilitated at peripheral recessed portion 1000 of the die mounting portion by forming (via laser ablation LB) therein sculpturing 1100—such as notches or trenches 1100 running along the recessed peripheral portion 1000.

FIG. 6 also illustrates that the peripheral recessed portion 1000 may be provided at the back/bottom surface of the die pad 12A in addition to (otherwise conventional) grooves G thus further reducing the risk of resin leaks undesirably covering the central portion of the second surface of the die pad 12A.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
forming a leadframe including a die pad having a first surface and a second surface opposite the first surface;
providing an adhesion promoter layer on at least the second surface of the die pad;
applying laser beam energy to the second surface of the die pad to selectively remove the adhesion promoter layer at a peripheral portion surrounding a central portion and further selectively remove material of the die pad at said peripheral portion to form, in the second surface of the die pad, a recessed peripheral portion surrounding the central portion;
mounting a semiconductor die to a die mounting region at the first surface of the die pad; and
molding an encapsulation of electrically insulating material onto the leadframe and the semiconductor die arranged on the die pad;
wherein electrically insulating material covers said recessed peripheral portion.

2. The method of claim 1, wherein the recessed peripheral portion of the second surface of the die pad has a depth in the range 25 to 35 microns.

3. The method of claim 1, further comprising roughening a surface at the recessed peripheral portion of the die pad is roughened, and wherein adhesion of the electrically insulating material to said recessed peripheral portion is facilitated by the roughened surface.

4. The method of claim 1, wherein forming the leadframe comprises providing the die pad with a raised rim at a periphery of the die pad, wherein said raised rim is embedded in the electrically insulating material, and wherein the recessed peripheral portion is positioned between the raised rim and the central portion.

5. The method of claim 1, further comprising sculpturing recessed features at a surface of the recessed peripheral portion, and wherein the electrically insulating material fills said recessed features.

6. A device, comprising:
a leadframe include a die pad having a first surface and a second surface opposite the first surface;
an adhesion promoter layer on the first and second surfaces of the die pad;
wherein the die pad includes a recessed peripheral portion at the second surface surrounding a central portion, where the adhesion promoter layer is not present at a surface of the recessed peripheral portion;
a semiconductor die arranged at the first surface of the die pad; and
an electrically insulating material encapsulating the leadframe and the semiconductor die;
wherein said electrically insulating material covers said recessed peripheral portion.

7. The device of claim 6, wherein the adhesion promoter layer completely covers all surfaces of the die pad except for the surface of the recessed peripheral portion.

8. The device of claim 6, wherein the recessed peripheral portion of the die pad has a depth in the range 25 to 35 microns.

9. The device of claim 6, wherein the surface of the recessed peripheral portion of the die pad is roughened.

10. The device of claim 6, wherein the die pad comprises a raised rim at a periphery of the die pad, wherein said raised rim is embedded in the electrically insulating material, and wherein the recessed peripheral portion is positioned between the raised rim and the central portion.

11. The device of claim 6, wherein the surface of the recessed peripheral portion includes groove or notch features, and wherein the electrically insulating material fills said groove or notch features.

12. The device of claim 6, further comprising grooves provided in the second surface of the die pad at the central portion.

13. A method, comprising:
mounting a semiconductor die to a die mounting region at a first surface of a die pad in a substrate, wherein the die pad has a second surface opposite the first surface;
applying laser beam energy to the second surface of the die pad to form in the second surface of the die pad a recessed peripheral portion surrounding a central portion, said central portion of the second surface of the die pad being opposite the die mounting region at the first surface; and
molding an encapsulation of electrically insulating material onto the substrate and the semiconductor die arranged thereon;
wherein during said molding the electrically insulating material covers said recessed peripheral portion with leakage of the electrically insulating material over said central portion being countered in response to the peripheral portion of the second surface of the die pad being recessed.

14. The method of claim 13 wherein the recessed peripheral portion of the second surface of the die pad has a depth in the range 25 to 35 microns.

15. The method of claim 13, wherein a surface at the recessed peripheral portion of the second surface of the die pad is roughened by the applied laser beam energy, and wherein adhesion of the electrically insulating material to said recessed peripheral portion is facilitated by the roughened surface.

16. The method of claim 13, wherein the die pad comprises a raised rim around the die mounting region at the first surface of the die pad, wherein said raised rim is embedded in the electrically insulating material during said molding, and wherein the recessed peripheral portion is positioned between the raised rim and the central portion.

17. The method of claim 13, further comprising:
providing an adhesion promoter layer on the second surface of the die pad; and
wherein applying laser beam energy to form the recessed peripheral portion of the second surface of the die pad comprises removing said adhesion promoter layer and a portion of the die pad to form the recessed peripheral portion.

18. The method of claim 13, further comprising forming sculpturing at the recessed peripheral portion of the second surface of the die pad, wherein adhesion of the electrically insulating material to said recessed peripheral portion is facilitated by said sculpturing.

19. A device, comprising:
a substrate having a die mounting region at a first surface of a die pad, wherein the die pad has a second surface opposite the first surface;
a semiconductor die arranged at the die mounting region;
wherein the die pad includes a recessed peripheral portion formed via laser beam energy applied to the second surface of the die pad, the recessed peripheral portion surrounding a central portion opposite the die mounting region at the first surface; and
an encapsulation of electrically insulating material molded onto the substrate and the semiconductor die;
wherein the electrically insulating material covers said recessed peripheral portion with leakage of the electrically insulating material over said central portion countered in response to the peripheral portion of the second surface of the die pad being recessed.

20. The device of claim 19, wherein the recessed peripheral portion of the second surface of the die pad has a depth in the range 25 to 35 microns.

21. The device of claim 19, wherein a surface of the recessed peripheral portion of the second surface of the die pad is roughened, with the electrically insulating material adhering to said roughened surface.

22. The device of claim 19, wherein the die pad comprises a raised rim around the die mounting region at the first surface of the die pad, wherein said raised rim is embedded in the electrically insulating material, and wherein the recessed peripheral portion is positioned between the raised rim and the central portion.

23. The device of claim 19, further comprising a sculpturing in a surface at the recessed peripheral portion of the die pad.

24. The device of claim 19, further comprising grooves provided at the central portion of the second surface of the die pad.

25. The device of claim 19, wherein an outer surface of the die pad is coverage by an adhesion promoter layer except at the recessed peripheral portion.
